(19) United States
(12) Patent Application Publication
(10) Pub. No.: US 2016/0064285 A1
(43) Pub. Date: Mar. 3, 2016

(54) MANUFACTURING METHOD FOR SEMICONDUCTOR DEVICE

(71) Applicant: PS4 LUXCO S.A.R.L.), Luxembourg (LU)

(72) Inventor: Yoshikazu MORIWAKI, Tokyo (JP)

(21) Appl. No.: 14/780,496

(22) PCT Filed: Mar. 20, 2014
(86) PCT No.: PCT/JP2014/057680

§ 371 Date: Sep. 25, 2015

(30) Foreign Application Priority Data
Mar. 27, 2013 (JP) 2013-066714

(51) Int. Cl. H01L 21/8238; H01L 21/02; H01L 27/108; H01L 21/66; H01L 21/321

(52) U.S. Cl. CPC H01L 21/82385; H01L 22/26; H01L 21/3212; H01L 27/10897; H01L 21/02532; H01L 21/02592

(57) ABSTRACT

On a peripheral circuit area upon a semiconductor substrate, an NMOS gate stack, comprising a first high-dielectric film, an NMOS gate metal, and a first semiconductor film, is formed, and a PMOS gate stack, comprising a second high-dielectric film, a PMOS gate metal, and a second semiconductor film, is formed so that a predetermined step is formed between the NMOS gate stack and the PMOS gate stack. A third semiconductor film is formed over the entire surface of the semiconductor substrate so as to fill in the step. The third semiconductor film is planarized by way of CMP so as to form a fourth semiconductor film that is thinner than the third semiconductor film.

### TECHNICAL FIELD

The present invention relates to a method for manufacturing a semiconductor device.

### BACKGROUND

As semiconductor devices become more sophisticated and more integrated, semiconductor devices having a high-κ metal gate transistor (referred to below as an HKMG transistor) in which a high-κ film is employed as a gate insulating film have come into use. In a semiconductor device having this HKMG transistor, the N-channel MOS (NMOS) transistor and the P-channel MOS (PMOS) transistor have different structures, so the NMOS gate stack and the PMOS gate stack have to be made separately.

For example, JP 2010-199610 A (Patent Document 1) and JP 2011-35229 A (Patent Document 2) describe a configuration comprising an HKMG transistor having an NMOS gate stack and an HKMG transistor having a PMOS gate stack on the same substrate.

### PATENT DOCUMENTS

Patent Document 1: JP 2010-199610 A

Patent Document 2: JP 2011-35229 A

### SUMMARY OF THE INVENTION

### Problem to be Solved by the Invention

When the NMOS gate stack and the PMOS gate stack are produced separately in a semiconductor device having the abovementioned HKMG transistor, a difference in level occurs between the NMOS gate stack and the PMOS gate stack, and therefore a seam is formed in a gate mask insulating film which is subsequently formed, and when the contact plugs and peripheral wiring are formed, the metal of the wires enters the seam and this leads to a problem in terms of short-circuiting between wires.

This problem will be described in detail with the aid of FIG. 16. FIG. 16 is an isometric diagram schematically representing part of a peripheral circuit region after peripheral wiring has been formed, and the boundary area between an NMOS transistor region and a PMOS transistor region is shown.

An NMOS gate stack 200 comprising a first high-κ film 201, an NMOS metal gate 202, and a first amorphous silicon film 203 is formed in an NMOS transistor region 4, and a PMOS gate stack 300 comprising a second high-κ film 301, a PMOS metal gate 302, and a second amorphous silicon film 303 are formed in a PMOS transistor region 5, and a difference in level D1 is present between the NMOS gate stack 200 and the PMOS gate stack 300.

When a third amorphous silicon film 502, a metal composite film 503 and a gate mask insulating film 504 constituting a peripheral gate 501 are formed during bit line gate formation, a seam D2 is produced in the gate mask insulating film 504 because of the difference in level D1. This seam D2 appears at the surface when peripheral wires 509 are subsequently formed, and the metal of the peripheral wires 509, e.g. a tungsten film 11, may enter the seam D2. In this case, if a plurality of peripheral wires 509 of different potential are applied to the same seam D2, a short-circuit D3 is produced through the tungsten film 11 that has entered the seam D2.

The present invention provides a method for manufacturing a semiconductor device, which makes it possible to prevent short-circuiting between wires without the formation of a seam in a gate mask insulating film in a peripheral circuit region.

### Means for Solving the Problem

The method for manufacturing a semiconductor device according to one mode of the present invention is characterized in that:
an NMOS gate stack comprising a first high-κ film, NMOS gate metal, and a first semiconductor film is formed in a peripheral circuit region on a semiconductor substrate;
a PMOS gate stack comprising a second high-κ film, PMOS gate metal, and a second semiconductor film is formed in the peripheral circuit region in such a way that a predetermined difference in level is formed with the NMOS gate stack;
a third semiconductor film is formed over the whole surface of the semiconductor substrate in such a way as to fill the difference in level; and
the third semiconductor film is planarized by means of CMP and a fourth semiconductor film which is thinner than the third semiconductor film is formed.

Furthermore, the method for manufacturing a semiconductor device according to another mode of the present invention is characterized in that:
an NMOS gate stack comprising a first high-κ film, NMOS gate metal, and a first semiconductor film is formed in a peripheral circuit region on a semiconductor substrate;
a second high-κ film, PMOS gate metal, and a second semiconductor film are formed over the whole surface of the semiconductor substrate;
the second semiconductor film is planarized until the PMOS gate metal is apparent on the NMOS gate stack, by means of CMP employing endpoint detection with the PMOS gate metal as a stopper; and
the second high-κ film, the PMOS gate metal, and the second semiconductor film are etched by means of etch-back until the upper surface of the first semiconductor film is apparent on the NMOS gate stack, and a PMOS gate stack comprising the second high-κ film, the PMOS gate metal and the second semiconductor film is formed.

### Advantage of the Invention

The present invention makes it possible to prevent short-circuiting between wires without the formation of a seam in a gate mask insulating film in a peripheral circuit region.

### BRIEF DESCRIPTION OF THE FIGURES

FIG. 1 is a plan view showing the arrangement of the main parts of a semiconductor device according to a mode of embodiment of the present invention;

FIG. 2 is a view in the cross section A-A in FIG. 1;

FIG. 3 is an isometric diagram showing the structure of a semiconductor device according to a first mode of embodiment of the present invention, where the cross section B-B in FIG. 1 is taken as the plane X-Z;

FIG. 4 is a view in cross section showing a step in the manufacture of the semiconductor device according to the first mode of embodiment of the present invention;

FIG. 5 is a view in cross section showing a step in the manufacture of the semiconductor device according to the first mode of embodiment of the present invention;

FIG. 6 is a view in cross section showing a step in the manufacture of the semiconductor device according to the first mode of embodiment of the present invention;

FIG. 7 is a view in cross section showing a step in the manufacture of the semiconductor device according to the first mode of embodiment of the present invention;

FIG. 8 is a view in cross section showing a step in the manufacture of the semiconductor device according to the first mode of embodiment of the present invention;

FIG. 9 is a view in cross section showing a step in the manufacture of the semiconductor device according to the first mode of embodiment of the present invention;

FIG. 10 is an isometric diagram showing the structure of a semiconductor device according to a second mode of embodiment of the present invention, where the cross section B-B in FIG. 1 is taken as the plane X-Z;

FIG. 11 is a view in cross section showing a step in the manufacture of the semiconductor device according to the second mode of embodiment of the present invention;

FIG. 12 is a view in cross section showing a step in the manufacture of the semiconductor device according to the second mode of embodiment of the present invention;

FIG. 13 is a view in cross section showing a step in the manufacture of the semiconductor device according to the second mode of embodiment of the present invention;

FIG. 14 is a view in cross section showing a step in the manufacture of the semiconductor device according to the second mode of embodiment of the present invention;

FIG. 15 is a view in cross section showing a step in the manufacture of the semiconductor device according to the second mode of embodiment of the present invention; and

FIG. 16 is an isometric diagram to illustrate the problems of the prior art, schematically representing part of the peripheral circuit region after peripheral wiring has been formed.

### MODE OF EMBODIMENT OF THE INVENTION

The method for manufacturing a semiconductor device, and a semiconductor device to which the present invention is applied will be described in detail below with reference to the figures. It should be noted that the figures used in the following description may be depicted with portions that constitute features being enlarged for the sake of convenience in order to facilitate an understanding of such features, and the dimensional proportions of the constituent elements do not necessarily correspond to the actual proportions. Furthermore, the materials and dimensions etc. given by way of example in the following description constitute one example but the present invention is not necessarily limited thereby and these may be varied, as appropriate, within a scope that does not alter the essential point of the present invention.

### First Mode of Embodiment

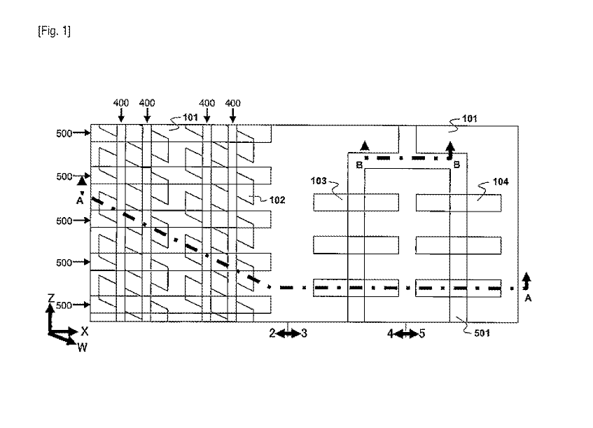

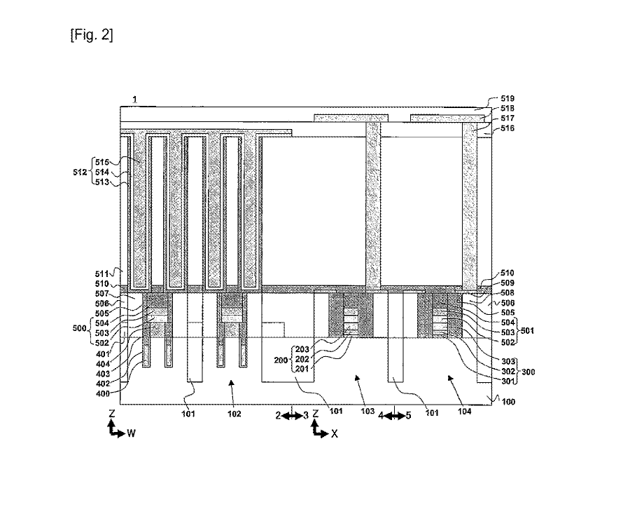

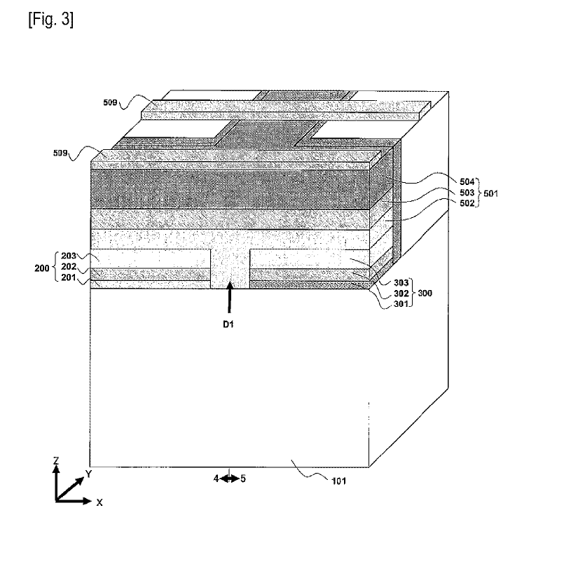

The structure of a semiconductor device according to a first mode of embodiment of the present invention will be described with the aid of FIG. 1 to FIG. 3. Here, FIG. 1 is a plan view showing the arrangement of the main parts of the semiconductor device. FIG. 2 corresponds to the cross section A-A in FIG. 1. FIG. 3 is an isometric diagram showing the detailed structure of the semiconductor device where the cross section B-B in FIG. 1 is taken as the plane X-Z.

FIG. 1 and FIG. 2 will be referred to first of all. A semiconductor device 1 functions ultimately as a DRAM, and a memory cell region 2 and a peripheral circuit region 3 located at the periphery of the memory cell region 2 are provided in the plane of a semiconductor substrate 100 (only the right-hand side of the memory cell region 2 is shown in FIG. 1). Here, the memory cell region 2 is a region in which a plurality of memory cells (not depicted) are arranged in the form of a matrix. Meanwhile, the peripheral circuit region 3 is a region in which circuits for controlling operations of the memory cells are formed, and it is divided into an NMOS transistor region 4 and a PMOS transistor region 5.

An element isolation region 101 is formed in such a way as to divide the surface of the semiconductor substrate 100, a plurality of memory cell active regions 102 which are inclined in the W-direction that is inclined from the X-direction are provided in alignment in the X-direction and the Y-direction in the memory cell region 2, NMOS active regions 103 are provided in alignment in the Y-direction in an NMOS transistor region 4, and PMOS active regions 104 are provided in alignment in the Y-direction in a PMOS transistor region 5.

Here, the shape, arrangement and number of memory cell active regions 102, NMOS active regions 103, and PMOS active regions 104 need not be as shown in the figures. Furthermore, a first interlayer insulating film is provided on the surface of the semiconductor substrate 100 in the memory cell region 2, and word lines 400 which extend in the Y-direction intersecting the memory cell active regions 102, divide the memory cell active regions 102 into three, and sandwich the first interlayer insulating film 402 with the memory cell active region 102 are also provided thereon. The upper part of the word lines 400 is sealed by a cap insulating film.

Furthermore, bit line contact plugs 404 are provided in such a way as to connect to the central portion of the memory cell active regions 102 lying between the word lines 400. Bit lines 500 extending in the X-direction are provided in such a way as to connect to the upper surfaces of the bit line contact plugs 404. The bit lines 500 comprise a third amorphous silicon film 502, a metal composite film 503, and a gate mask insulating film 504.

Furthermore, a peripheral gate 501 is provided on a central portion of the plurality of NMOS active regions 103 with an NMOS gate stack 200 interposed. The NMOS gate stack 200 comprises a first high-κ film 201, NMOS gate metal 202, and a first amorphous silicon film 203.

Furthermore, the peripheral gate 501 is provided on a central portion of the plurality of PMOS active regions 104 with a PMOS gate stack 300 interposed. The PMOS gate stack 300 comprises a second high-κ film 301, PMOS gate metal 302, and a second amorphous silicon film 303. The peripheral gate 501 has the same structure as the bit lines 500.

Furthermore, a liner film 505 is provided on the side surfaces of the bit lines 500 and the peripheral gate 501, and a second interlayer insulating film 506 is provided in such a way as to cover the bit lines 500, peripheral gate 501, and liner film 505, and is planarized by means of CMP until the gate mask insulating film 504 is apparent. Capacitor contact plugs 507 are provided in such a way as to connect at both ends either side of the word lines 400 to the memory cell active regions 102 through the second interlayer insulating film 506.

Furthermore, peripheral contact plugs 508 are provided in such a way as to connect at both ends either side of the peripheral gate 501 to the NMOS active regions 103 and PMOS active regions 104 through the second interlayer insulating film 506, and peripheral wires 509 are provided in such a way as to connect to the upper surfaces of the peripheral contact plugs 508.

Furthermore, a stopper film 510 is provided in such a way as to cover the whole surface of the semiconductor substrate 100 including the upper surfaces of the capacitor contact plugs 507 and the peripheral wires 509. A third interlayer insulating film 511 is provided on the stopper film 510. Capacitors 512 comprising an upper electrode 515, a capacitor insulating film 514 and a lower electrode 513 connected to the upper surface of the capacitor contact plug 507 are provided through the third interlayer insulating film 511 and the stopper film 510.

A fourth interlayer insulating film 516 is provided in such a way as to cover the upper surface of the capacitors 512 and the third interlayer insulating film 511. Wiring contact plugs 517 connecting to the peripheral wires 509 are provided through the fourth interlayer insulating film 516, third interlayer insulating film 511, and stopper film 510. Wires 518 are provided in such a way as to connect to the upper surfaces of the wiring contact plugs 517. A protective insulating film 519 is provided in such a way as to cover the wires 518.

FIG. 3 will be referred to next. The NMOS gate stack 200 and PMOS gate stack 300 remain at the lower part of the peripheral gate 501 on the element isolation region 101 in the NMOS transistor region 4 and the PMOS transistor region 5 in accordance with the manufacturing steps, and a difference in level D1 is present between the NMOS gate stack 200 and the PMOS gate stack 300. The peripheral gate 501 is provided, and this comprises the gate mask insulating film 504, the metal composite film 503, and the third amorphous silicon film 502 which fills the difference in level D1 and is planarized at the upper surface by CMP.

Here, the difference in level D1 is filled by the third amorphous silicon film 502 and the upper surface of the third amorphous silicon film 502 is planarized, so a seam is not produced in the gate mask insulating film 504. Short-circuiting is therefore unlikely to occur in the peripheral wires 509.

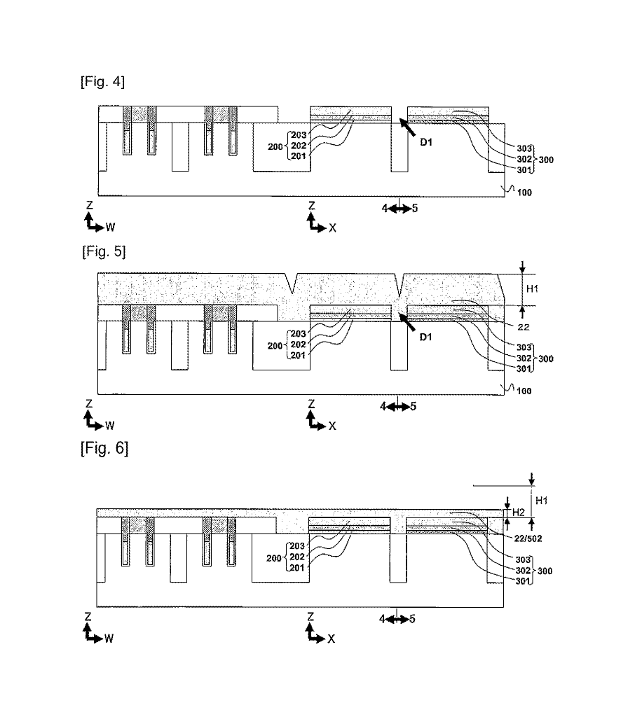

The method for manufacturing the semiconductor device 1 according to the first mode of embodiment will be described next with the aid of FIG. 4 to FIG. 9.

FIG. 4 will be referred to first of all. A first interlayer insulating film, word lines, and bit contact plugs are formed by a known method on the surface of a semiconductor substrate 100.

An NMOS gate stack 200 comprising a first high-κ film 201, NMOS gate metal 202, and a first amorphous silicon film 203, and a PMOS gate stack 300 comprising a second high-κ film 301, PMOS gate metal 302 and a second amorphous silicon film 303 are then formed by means of a known method. Here, a difference in level D1 is present between the NMOS gate stack 200 and the PMOS gate stack 300.

FIG. 5 will be referred to next. An amorphous silicon film 22 is formed to a thickness H1 (e.g., 60 nm) on the surface of the semiconductor substrate 100 by means of conventional CVD in such a way as to fill the difference in level D1.

FIG. 6 will be referred to next. The amorphous silicon film 22 is planarized to a thickness H2 (e.g., 10 nm) on the first amorphous silicon film 203 and the second amorphous silicon film 303, thereby forming a third amorphous silicon film 502.

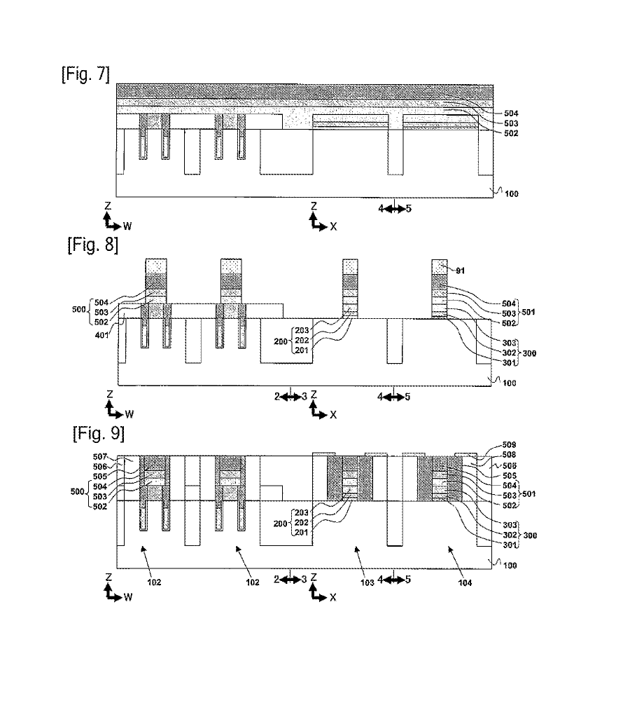

FIG. 7 will be referred to next. A metal composite film 503 and a gate mask insulating film 504 are formed using conventional processing conditions and apparatus. As mentioned above, the surface of the third amorphous silicon film 502 is planarized, so a seam D2 is not formed in the gate mask insulating film 504. As a result, it is possible to make it unlikely for short-circuiting to occur in the peripheral wires 509 which are subsequently formed.

FIG. 8 will be referred to next. A resist 91 is coated over the whole surface of the semiconductor substrate 100 and the gate mask insulating film 504 is processed to the shape of the bit lines 500 and the peripheral gate 501 by means of lithography and dry etching. The metal composite film 503 and the third amorphous silicon film 502 are then etched in the memory cell region 2 using the gate mask insulating film 504 as a mask, while the metal composite film 503, third amorphous silicon film 502, and NMOS gate stack 200 are etched in the NMOS transistor region 4, and the metal composite film 503, third amorphous silicon film 502, and PMOS gate stack 300 are etched in the PMOS transistor region 5. The remaining gate mask insulating film 504, metal composite film 503, and third amorphous silicon film 502 form the bit lines 500 and peripheral gate 501.

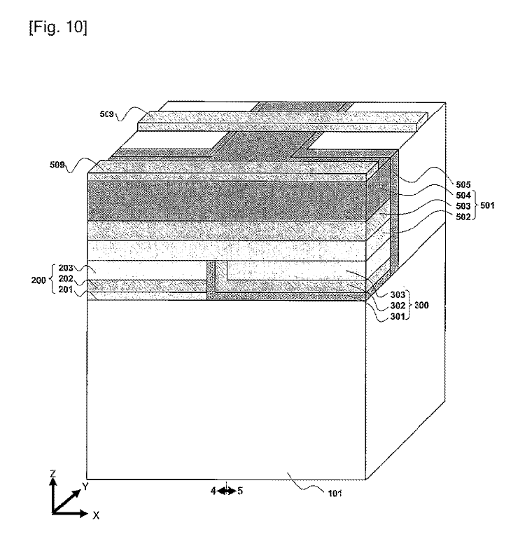

FIG. 9 will be referred to next. A liner film 505 is formed by a known method on the side surfaces of the bit lines 500, peripheral gate 501, NMOS gate stack 200, and PMOS gate stack 300, the whole structure is filled by an oxide film or an SOD film, planarization is then performed by means of CMP until the gate mask insulating film 504 is apparent, and a second interlayer insulating film 506 is formed.

Capacitor contact plugs 507 connecting to the memory cell active regions 102 are then formed by a known method in the memory cell region 2, peripheral contact plugs 508 connecting to the NMOS active regions 103 are formed in the NMOS transistor region 4, and peripheral contact plugs 508 connecting to the PMOS active regions 104 are formed in the PMOS transistor region 5.

Peripheral wires 509 connecting to the upper surfaces of the peripheral contact plugs 508 are then formed by a known method. Here, there is no seam in the gate mask insulating film 504, so it is possible to make it unlikely for short-circuiting to occur between the peripheral wires 509.

A stopper film 510 and a third interlayer insulating film 511 are then formed over the whole surface of the semiconductor substrate 100 including the peripheral wires 509, and capacitors 512, a fourth interlayer insulating film 516, wiring contact plugs 517, wires 518, and a protective insulating film 519 are formed; the semiconductor device 1 shown in FIG. 1 and FIG. 2 is completed by this step.

### Second Mode of Embodiment

The structure of a second mode of embodiment of the present invention will be described next with the aid of FIG. 10.

FIG. 10 is an isometric diagram showing the structure of the second mode of embodiment of the present invention, and corresponds to FIG. 3 in the first embodiment. It should be noted that elements which are the same as in the first mode of embodiment will not be described again and the same reference symbols are used in this figure.

FIG. 10 will be referred to. An NMOS gate stack 200 comprising a first high-κ film 201, NMOS gate metal 202, and a first amorphous silicon film 203 is provided in an NMOS transistor region 4. Furthermore, a second high-κ film 301, PMOS gate metal 302, and a second amorphous silicon film 303 are formed over the whole surface of a semiconductor substrate 100 including the NMOS gate stack 200, and a PMOS gate stack 300 cut back by CMP and etch-back is provided up to the height of the upper surface of the NMOS gate stack 200.

Furthermore, a peripheral gate 501 comprising a third amorphous silicon film 502, a metal composite film 503, and a gate mask insulating film 504 is provided on the NMOS gate stack 200 and the PMOS gate stack 300. Here, there is no difference in level between the NMOS gate stack 200 and the PMOS gate stack 300, so a seam is not formed in the gate mask insulating film 504. Short-circuiting is therefore unlikely to occur in the peripheral wires 509.

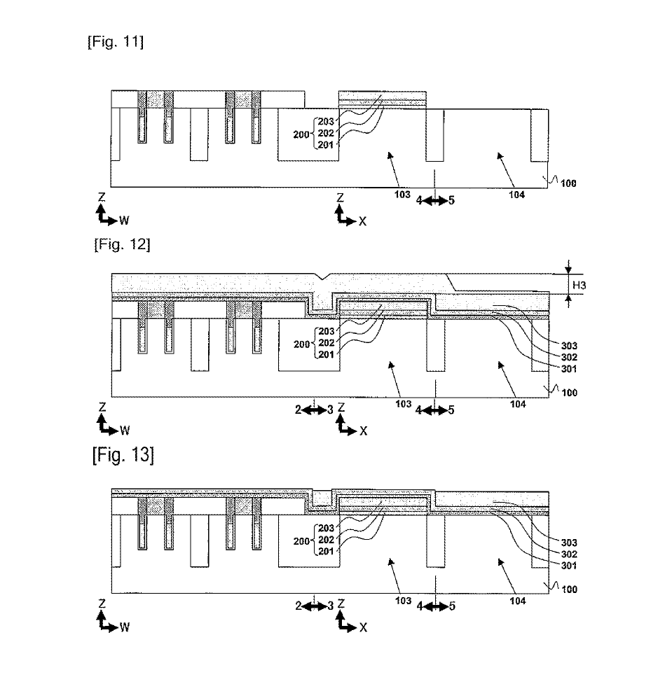

The method for manufacturing the semiconductor device 1 according to the second mode of embodiment will be described next with the aid of FIG. 11 to FIG. 15.

Furthermore, elements which are the same as in the method for manufacturing a semiconductor device according to the first mode of embodiment described above will not be described in the following text and the same reference symbols are used in the figures.

FIG. 11 will be referred to first of all. A first interlayer insulating film, word lines and bit contact plugs are formed by a known method on the surface of a semiconductor substrate 100.

An NMOS gate stack 200 comprising a first high-κ film 201, NMOS gate metal 202, and a first amorphous silicon film 203 is then formed by a known method.

FIG. 12 will be referred to next. A second high-κ film 301, PMOS gate metal 302, and a second amorphous silicon film 303 are formed over the whole surface of the semiconductor substrate 100. The thickness of the second amorphous silicon film 303 is 60 nm, for example.

FIG. 13 will be referred to next. The second amorphous silicon film 303 is planarized until the gate metal 302 is apparent, by means of CMP employing endpoint detection in which the gate metal 302 serves as a stopper. Here, the endpoint detection is carried out by automatically stopping CMP on the gate metal 302 in accordance with torque variations during said CMP.

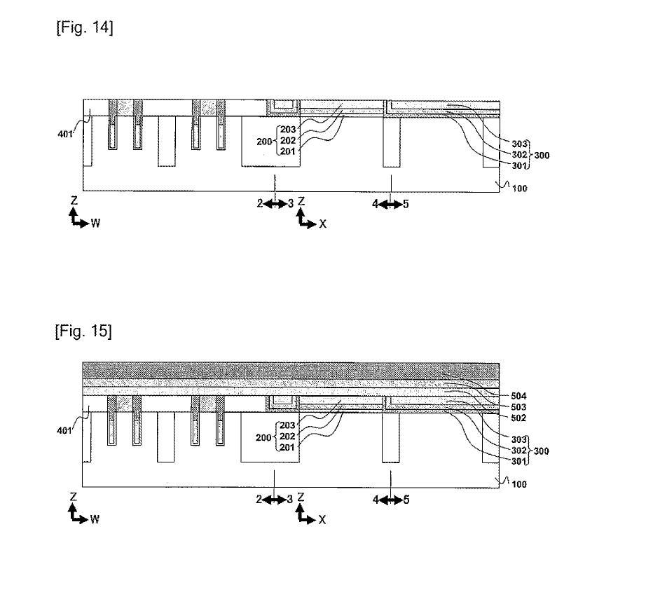

FIG. 14 will be referred to next. The upper surface of the first amorphous silicon film 203 is etched by means of etch-back. As a result, a PMOS gate stack 300 comprising the second high-κ film 301, PMOS gate metal 302, and second amorphous silicon film 303 is formed. Here, the PMOS gate stack 300 forms a negative pattern of the NMOS gate stack 200 and there is no difference in level between the NMOS gate stack 200 and the PMOS gate stack 300. Furthermore, lithography is not used to form the PMOS gate stack 300 so it is possible to reduce the number of steps involved and to reduce the manufacturing costs.

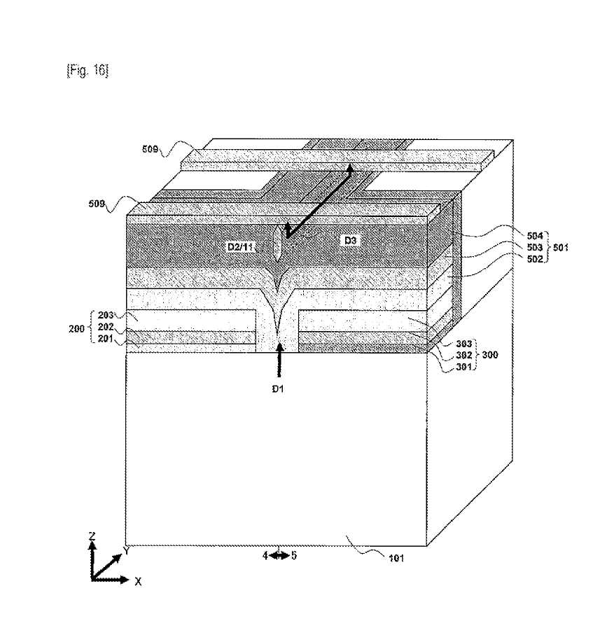

FIG. 15 will be referred to next. A third amorphous silicon film 502, metal composite film 503 and gate mask insulating film 504 are formed using conventional processing conditions and apparatus. As mentioned above, there is no difference in level between the NMOS gate stack 200 and the PMOS gate stack 300, so a seam D2 is not formed in the gate mask insulating film 504. As a result, it is possible to make it unlikely for short circuiting to occur in the peripheral wires 509 which are subsequently formed. The semiconductor 1 shown in FIG. 1 and FIG. 2 is subsequently completed via the same steps as in the first mode of embodiment.

In the first mode of embodiment described above, the third amorphous silicon film 502 is formed thickly in such a way as to fill the difference in level D1 which is produced between the NMOS gate stack 200 and the PMOS gate stack 300, planarization is performed by means of CMP, and the difference in level D1 formed between the NMOS gate stack 200 and the PMOS gate stack 300 is planarized. According to the first mode of embodiment, the difference in level D1 formed between the NMOS gate stack 200 and the PMOS gate stack 300 is filled, so it is possible to make it unlikely for short-circuiting to occur between the wires, without the formation of a seam in the gate mask insulating film 504.

Furthermore, the second mode of embodiment described above includes a manufacturing step in which the second amorphous silicon film 303 is planarized by CMP, and the CMP is automatically stopped on the gate metal 302 of the PMOS gate stack 300 by means of endpoint detection in accordance with torque variations during CMP. According to the second mode of embodiment, the CMP is automatically stopped by means of endpoint detection, and as a result a resist is not needed to form the PMOS gate stack 300 and costs can be reduced by reducing the number of steps involved.

Preferred modes of embodiment of the present invention have been described above, but the present invention is not limited to the abovementioned modes of embodiment and various modifications are possible within a scope that does not depart from the essential point of the present invention, and any such modifications are of course included in the scope of the present invention.

The present application claims the benefit of priority on the basis of Japanese Patent Application 2013-66714 filed on Mar. 27, 2013, the disclosure of which is incorporated herein in its entirety as a reference document.

### KEY TO SYMBOLS

1 . . . Semiconductor device
2 . . . Memory cell region
3 . . . Peripheral circuit region
4 . . . NMOS transistor region
5 . . . PMOS transistor region
91 . . . Resist
100 . . . Semiconductor substrate
101 . . . Element isolation region
102 . . . Memory cell active region
103 . . . NMOS active region
104 . . . PMOS active region
200 . . . NMOS gate stack
201 . . . First high-κ film
202 . . . NMOS gate metal
203 . . . First amorphous silicon film
300 . . . PMOS gate stack
301 . . . Second high-κ film
302 . . . PMOS gate metal
303 . . . Second amorphous silicon film
400 . . . Word line
402 . . . First interlayer insulating film
404 . . . Bit line contact plug
500 . . . Bit line
501 . . . Peripheral gate
502 . . . Third amorphous silicon film
503 . . . Metal composite film
504 . . . Gate mask insulating film
505 . . . Liner film
506 . . . Second interlayer insulating film
507 . . . Capacitor contact plug
508 . . . Peripheral contact plug
509 . . . Peripheral wire
510 . . . Stopper film
511 . . . Third interlayer insulating film
512 . . . Capacitor
513 . . . Lower electrode
514 . . . Capacitor insulating film
515 . . . Upper electrode
516 . . . Fourth interlayer insulating film
517 . . . Wiring contact plug
518 . . . Wire
519 . . . Protective insulating film

1. A method for manufacturing a semiconductor device, comprising:
forming an NMOS gate stack comprising a first high-κ film, NMOS gate metal, and a first semiconductor film in a peripheral circuit region on a semiconductor substrate;
forming a PMOS gate stack comprising a second high-κ film, PMOS gate metal, and a second semiconductor film in the peripheral circuit region in such a way that a predetermined difference in level is formed with the NMOS gate stack;
forming a third semiconductor film over the whole surface of the semiconductor substrate in such a way as to fill the difference in level; and
planarizing the third semiconductor film by means of CMP and forming a fourth semiconductor film which is thinner than the third semiconductor film.

2. The method for manufacturing a semiconductor device as claimed in claim 1, comprising:
forming a metal composite film and a gate mask insulating film on the planarized fourth semiconductor film; and
forming a peripheral gate by the fourth semiconductor film, the metal composite film, and the gate mask insulating film.

3. The method for manufacturing a semiconductor device as claimed in claim 1, wherein formation of a seam inside the gate mask insulating film is prevented by forming the gate mask insulating film on the planarized fourth semiconductor film.

4. The method for manufacturing a semiconductor device as claimed in claim 3, comprising:
forming peripheral wires on the peripheral gate; and
preventing short-circuiting between the peripheral wires by preventing formation of the seam.

5. The method for manufacturing a semiconductor device as claimed in claim 1, wherein the first, second, third and fourth semiconductor films are amorphous silicon films.

6. A method for manufacturing a semiconductor device, comprising:
forming an NMOS gate stack comprising a first high-κ film, NMOS gate metal, and a first semiconductor film is formed in a peripheral circuit region on a semiconductor substrate;
forming a second high-κ film, PMOS gate metal, and a second semiconductor film over the whole surface of the semiconductor substrate;
planarizing the second semiconductor film until the PMOS gate metal is apparent on the NMOS gate stack, by means of CMP employing endpoint detection with the PMOS gate metal as a stopper; and
etching the second high-κ film, the PMOS gate metal, and the second semiconductor film by means of etch-back until the upper surface of the first semiconductor film is apparent on the NMOS gate stack, and forming a PMOS gate stack comprising the second high-κ film, the PMOS gate metal and the second semiconductor film.

7. The method for manufacturing a semiconductor device as claimed in claim 6, wherein the endpoint detection is carried out by automatically stopping CMP on the PMOS gate metal in accordance with torque variations during said CMP.

8. The method for manufacturing a semiconductor device as claimed in claim 6, wherein or the PMOS gate stack is taken as a negative pattern of the NMOS gate stack, the method being performed in such a way that a difference in level is not produced between the NMOS gate stack and the PMOS gate stack.

9. The method for manufacturing a semiconductor device as claimed in claim 8, wherein lithography is not used to form the PMOS gate stack.

10. The method for manufacturing a semiconductor device as claimed in claim 6, comprising:
forming a metal composite film and a gate mask insulating film on the planarized second semiconductor film; and
forming a peripheral gate by the second semiconductor film, the metal composite film, and the gate mask insulating film.

11. The method for manufacturing a semiconductor device as claimed in claim 10, wherein the formation of a seam inside the gate mask insulating film is prevented by forming the gate mask insulating film on the planarized second semiconductor film.

12. The method for manufacturing a semiconductor device as claimed in claim 11, comprising:
forming peripheral wires on the peripheral gate; and
preventing short-circuiting between the peripheral wires by preventing formation of the seam.

13. The method for manufacturing a semiconductor device as claimed in claim 6, wherein the first and second semiconductor films are amorphous silicon films.
